(19) United States
(12) Patent Application Publication
(10) Pub. No.: US 2014/0292444 A1
(43) Pub. Date: Oct. 2, 2014

(54) ELASTIC WAVE FILTER

(71) Applicant: NIHON DEMPA KOGYO CO., LTD., TOKYO (JP)

(72) Inventors: OSAMU TOKUDA, SAITAMA (JP); TADAAKI TSUDA, SAITAMA (JP)

(73) Assignee: NIHON DEMPA KOGYO CO., LTD., TOKYO (JP)

(21) Appl. No.: 14/226,831

(22) Filed: Mar. 27, 2014

(30) Foreign Application Priority Data
Mar. 28, 2013 (JP) 2013-069436

(51) Int. Cl. H03H 9/64

(52) U.S. Cl. CPC H03H 9/14547; H03H 9/64
USPC 333/194

(57) ABSTRACT

An elastic wave filter includes an electrode finger group in an input side electrode and an electrode finger group in output side electrode each disposed in a taper shape such that elastic waves with mutually different wavelengths propagate on a piezoelectric substrate across from a track Tr1 at a low frequency side of a passband to a track Tr2 at a high frequency side of the passband. Assuming that a period length P is a wavelength of the elastic wave propagating on the piezoelectric substrate and constituted of a width dimension of the finger and a separation dimension between the adjacent electrode fingers, at least one of the input side IDT electrode and the output side IDT electrode includes a specific configuration.

### CROSS REFERENCE TO RELATED APPLICATION

This application claims the priority benefits of Japanese application serial no. 2013-069436, filed on Mar. 28, 2013. The entirety of the above-mentioned patent application is hereby incorporated by reference herein and made a part of this specification.

### FIELD OF THE INVENTION

This disclosure relates to an elastic wave filter that includes an electrode finger group in a taper shape.

### DESCRIPTION OF THE RELATED ART

There is a tapered filter known as a filter (band-pass filter) that employs elastic wave such as a surface acoustic wave (SAW). As illustrated in FIG. 17, the tapered filter includes an Inter Digital Transducer (IDT) electrode 103, which includes a number of electrode fingers 102 arranged in a taper shape in a region between a pair of busbars 101 and 101, as input and output electrodes on a piezoelectric substrate 104. In this filter, one side (back side) of the pair of busbars 101 and 101 has a track Tr1 corresponding to the minimum frequency (the lower end frequency) in a passband of the filter, while the other side (front side) of the pair of busbars 101 and 101 has a track Tr2 corresponding to the maximum frequency (the upper end frequency). In FIG. 17, a reference numeral 105 denotes a shield electrode, and a reference numeral 106 denotes a damper.

In this type of filter, attempting to have a wider bandwidth while keeping the dimension of the filter compact causes a decreased taper angle degree θ (reclined) of the IDT electrode 103, and the decreased taper angle degree θ causes elastic waves of the filter to be prone to diffraction and refraction. Additionally, as illustrated by the one dot chain line (Conventional 1) in FIG. 5, the diffraction and refraction as the result of the decreased taper angle degree θ cause what is called “rounded edge” of an attenuation curve. The “rounded edge” causes, for example, a narrowed pass bandwidth compared with the setting and deteriorates attenuation amount near the band (especially, the high frequency side).

Japanese patent No. 4707902 discloses a configuration where an extended track at the high frequency side or an extended track at the low frequency side is disposed in a tapered filter so as to suppress the characteristics deterioration due to the diffraction and refraction. The configuration is, as illustrated in FIG. 18, for example, at the track Tr2 corresponding to the maximum frequency in the passband of the filter, the electrode finger 102 has a length longer than the electrode fingers of other tracks. However, although this configuration ensures the improved characteristics compared with the above-described filter in FIG. 17, as illustrated by a dashed line (Conventional 2) in FIG. 5, the attenuation curve rises near the track Tr2 (the maximum frequency in the passband). Consequently, the flatness deteriorates in the passband, and the pass bandwidth becomes wider than the setting. While Japanese Patent No. 4768113 and Japanese Unexamined Patent Application Publication Nos. 6-90132, 2-72709, and 2010-171805 disclose various examinations on configurations and layouts of the fingers in the filter, a satisfactory preferred result has not been obtained.

A need thus exists for an elastic wave filter which is not susceptible to the drawbacks mentioned above.

### SUMMARY OF THE INVENTION

An elastic wave filter according to the disclosure includes an electrode finger group in an input side electrode and an electrode finger group in output side electrode with each electrode finger group disposed in a taper shape such that elastic waves with mutually different wavelengths propagate on a piezoelectric substrate across from a track Tr1 at a low frequency side of a passband to a track Tr2 at a high frequency side of the passband. The input side electrode and the output side electrode each includes a pair of busbars and a plurality of electrode fingers to constitute an input side IDT electrode and an output side IDT electrode respectively. The pair of busbars each extends along a propagation direction of the elastic wave and is arranged mutually separated in a direction perpendicular to the propagation direction. The plurality of electrode fingers alternately extends from each of the pair of busbars toward the opposite busbar in a comb shape between the pair of busbars. Assuming that a period length P is a wavelength of the elastic wave propagating on the piezoelectric substrate and constituted of a width dimension of the finger and a separation dimension between the adjacent electrode fingers, at least one of the input side IDT electrode and the output side IDT electrode includes at least one of following configurations: (1) The respective electrode fingers are arranged such that the period length P decreases from a period length PTr1 at the track Tr1 to a period length PTr2 at the track Tr2 in one region, the respective electrode fingers are arranged such that the period length P increases from a period length PTr3 at a track Tr3 to a period length PTr4 at a track Tr4 in another region, the one region and the other region are arranged to dispose the track Tr2 and the track Tr3 adjacent, the respective electrode fingers opposed one another between the one region and the other region are connected, and PTr1≧PTr4>PTr3=PTr2; and (2) The respective electrode fingers are arranged such that the period length P decreases from the period length PTr1 at the track Tr1 to the period length PTr2 at the track Tr2 in one region, the respective electrode fingers are arranged such that the period length P decreases from a period length PTr5 at a track Tr5 to a period length PTr6 at a track Tr6 in another region, the one region and the other region are arranged to dispose the track Tr1 and the track Tr5 adjacent, the respective electrode fingers opposed one another between the one region and the other region are connected, and PTr1=PTr5>PTr6≧PTr2.

### BRIEF DESCRIPTION OF THE DRAWINGS

The foregoing and additional features and characteristics of this disclosure will become more apparent from the following detailed description considered with the reference to the accompanying drawings.

FIG. 1 is a plan view illustrating an exemplary elastic wave filter according to this disclosure.

FIG. 2 is a partially enlarged plan view of the elastic wave filter.

FIG. 3 is a characteristic diagram schematically illustrating characteristics of the elastic wave filter.

FIG. 4 is a characteristic diagram schematically illustrating characteristics of the elastic wave filter.

FIG. 5 is a characteristic diagram illustrating characteristics of the elastic wave filter.

FIG. 6 is a schematic diagram illustrating characteristics of the elastic wave filter.

FIG. 7 is a plan view illustrating another exemplary elastic wave filter according to this disclosure.

FIG. 8 is a partially enlarged plan view of the other exemplary elastic wave filter.

FIG. 9 is a characteristic diagram schematically illustrating characteristics of the other exemplary elastic wave filter.

FIG. 10 is a plan view illustrating yet another exemplary elastic wave filter according to this disclosure according to this disclosure.

FIG. 11 is a partially enlarged plan view illustrating the yet another elastic wave filter.

FIG. 12 is a characteristic diagram schematically illustrating characteristics of the yet another elastic wave filter.

FIG. 13 is a partially enlarged plan view illustrating yet another exemplary elastic wave filter according to this disclosure.

FIG. 14 is a partially enlarged plan view illustrating yet another exemplary elastic wave filter.

FIG. 15 is a characteristic diagram schematically illustrating characteristics of the yet another exemplary elastic wave filter.

FIG. 16 is a characteristic diagram schematically illustrating characteristics of yet another exemplary elastic wave filter according to this disclosure.

FIG. 17 is a plan view illustrating a conventional filter.

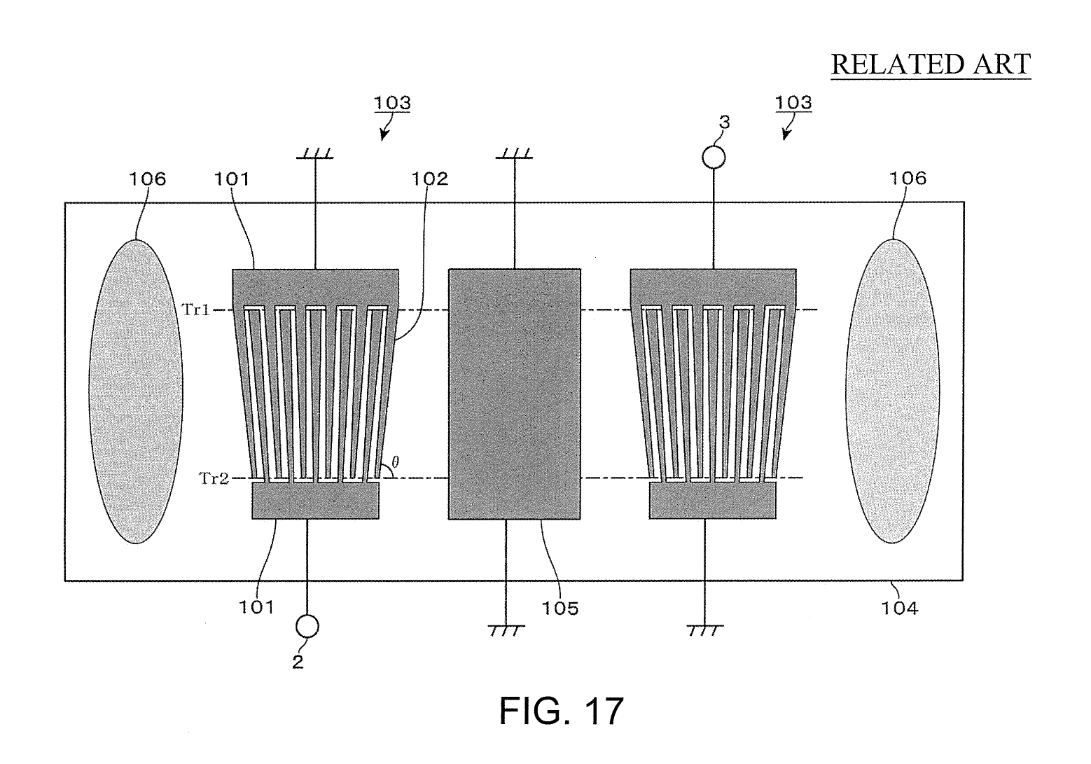

FIG. 18 is a plan view illustrating a conventional filter.

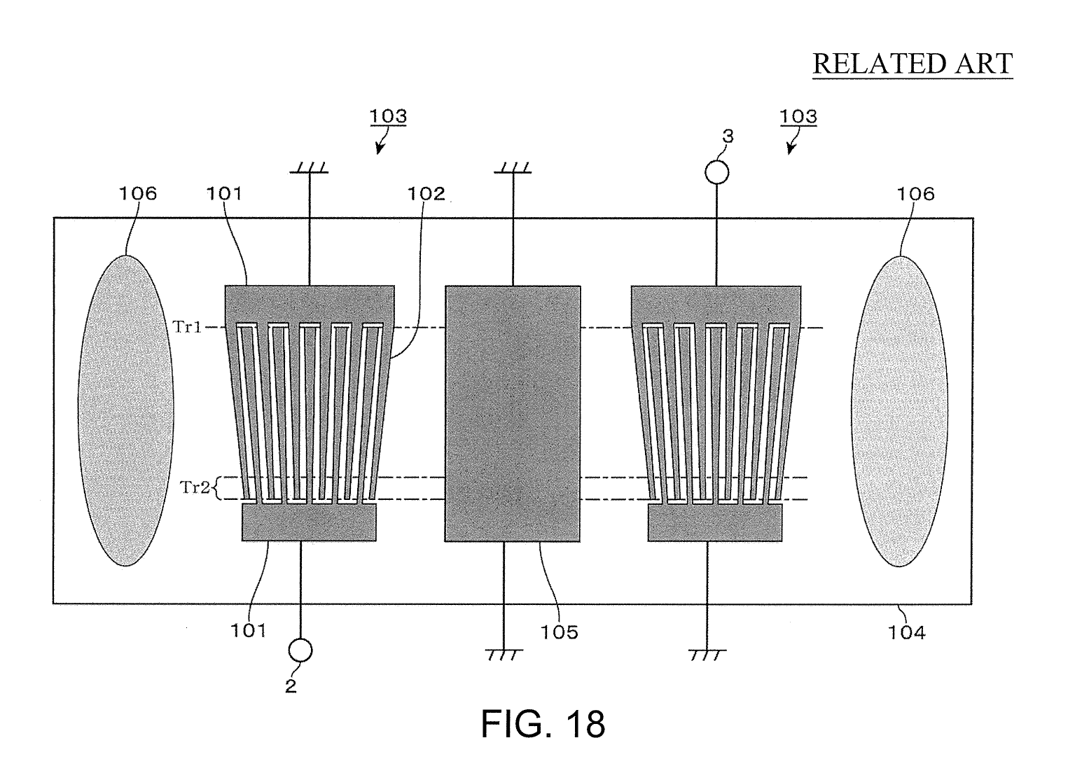

### DETAILED DESCRIPTION

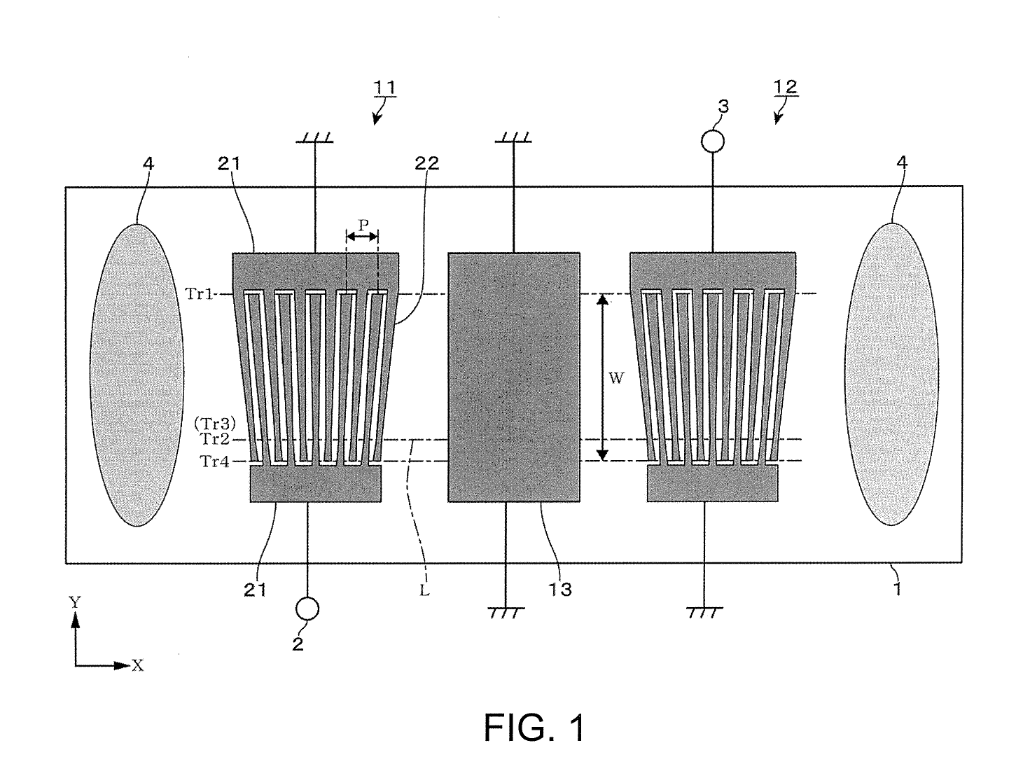

A description will be given for an embodiment of an elastic wave filter according to this disclosure by referring to FIG. 1 to FIG. 3. This elastic wave filter includes an input-side IDT electrode 11, an output-side IDT electrode 12, and a shield electrode 13, which is arranged between the IDT electrodes 11 and 12. The elastic wave filter is formed on a piezoelectric substrate 1 made of material such as quartz-crystal and lithium niobate (LiNbO3). The elastic wave filter is a band pass filter that has a passband and stopbands provided in ranges of frequencies higher and lower than the frequency of the passband. As it will be described later, the elastic wave filter is configured with the tapered IDT electrodes 11 and 12 to suppress filter characteristic deterioration caused by diffraction and refraction of elastic waves. In FIG. 1, a reference numeral 2 denotes an input port, a reference numeral 3 denotes an output port, and a reference numeral 4 denotes a damper constituted of materials such as resin that is used to absorb unnecessary elastic waves. Also, FIG. 1 illustrates the IDT electrodes 11 and 12 in a partially simplified manner.

The input-side IDT electrode 11 includes a pair of busbars 21 and 21 and a plurality of electrode fingers 22 tapered between these busbars 21 and 21. In other words, the busbars 21 and 21 are arranged such that each of the busbars 21 and 21 extends along the propagation direction (X direction) of elastic waves while the busbars 21 and 21 are positioned away from each other in a direction orthogonal to the propagation direction (Y direction). The electrode fingers 22 are arranged to alternately extend from each of the busbars 21 and 21 towards the opposite busbar of the busbars 21 and 21 so as to form a comb shape.

Here, the wavelength of the elastic waves propagating on the piezoelectric substrate 1 is called a pitch P (period length). In other words, as illustrated in FIG. 1, each of the electrode fingers 22 is arranged such that its pitch P continuously changes within the pair of busbars 21 and 21. Here, the pitch P is a dimension between the center lines of respective two electrode fingers 22 and 22, and the electrode fingers 22 extend in adjacent to each other from the front busbars 21 to the back busbars 21.

Specifically, in a region close to the back busbar 21, the electrode fingers 22 are formed with a pitch PTr1 corresponding to a track Tr1 so as to allow propagation of the elastic waves of the track Tr1, which corresponds to the lower end frequency in the passband. A virtual line, which extends along the busbars 21 at a distance of dimension D1 away from the front busbar 21 toward the back busbar 21, is denoted by symbol “L.”. From the back busbar 21 to the line L, the pitch P continuously decreases from the above-described pitch PTr1 to the pitch PTr2 at a track Tr2, which corresponds to the upper end frequency in the passband.

At the front side of the line L, the pitch P continuously increases towards the front busbar 21, from the pitch PTr3 at a track Tr3 to the pitch PTr4 at a track Tr4. In this example, the track Tr2 and track Tr3 have the same pitch P dimension. Thus, on the input-side IDT electrode 11, each of the electrode fingers 22 is formed with the pitch P increasing from the line L to the back side and from the line L to the front side such that the track Tr2 (Tr3), which corresponds to the upper end frequency in the passband, is not formed in a position corresponding to the busbar, since the pitch P increases from the line L to the back side and from the line L to the front side. Specifically, the pitches PTr1, PTr2 (PTr3), and PTr4 are 22.61 μm, 19.16 μm, and 19.66 μm, respectively. Thus, the ratio of PTr2 (PTr3):PTr4 is between 1:1.02 and 1:1:1.2.

The separation dimension between the busbars 21 and 21 is called “aperture W”. If the separation dimension D1 between the line L and the front busbar 21 is too long, the elastic wave filter may become too large. On the other hand, if the separation dimension D1 is too short, the elastic waves become prone to diffraction at the front side of the line L. Thus, the separation dimension D1 is 0.5% to 3% of the aperture W. In this example, the separation dimension D1 is 2.9% of the aperture W. The separation dimension D1 is preferably 0.7% to 1.5% of the aperture W. When the aperture W is defined as a function of the pitch PTr0 (=(PTr1+PTr2)/2) at a track Tr0, which corresponds to the center frequency f0 in the passband of the elastic wave filter, the aperture W could be 51.5 PTr0 as an example.

In this example, at the back side and front side of the line L, the taper angles of the electrode fingers 22 are equal. Therefore, the pitch P at a distance of dimension D1 away from the line L toward the back side has the same dimension as the pitch PTr4 at a track Tr4, which is close to the front busbar 21.

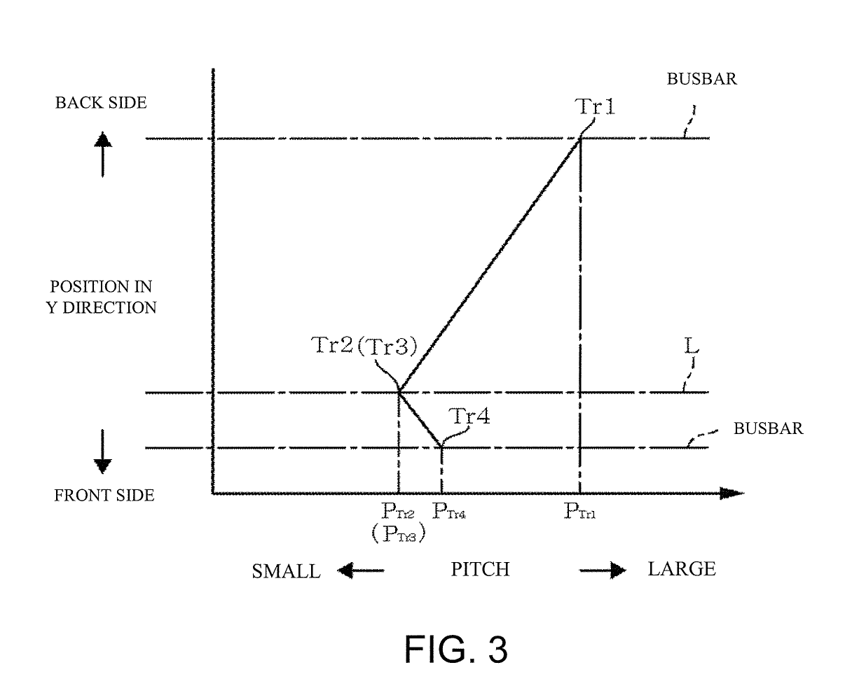

In summary, it can be said that the input-side IDT electrode 11 is configured to allow propagation of the elastic waves of the tracks Tr1 to Tr2, which correspond to the passband, at the back side of the line L, while the input-side IDT electrode 11 also has a propagation region for the tracks Tr3 to Tr4, which structurally is a part of the tracks Tr1 and Tr2 (corresponding to the high frequency side in the passband), at the front side of the line L. The electrode fingers 22 are also formed to match the pitch P at the track Tr2 and the pitch P at the track Tr3 and to place the tracks Tr2 and Tr3 in adjacent to each other (or overlapped each other). Also, in the region at the back side of the line L and in the region at the front side of the line L, the electrode fingers 22, which face each other, are connected with each other at the line L. Thus, as described above, the track Tr2, which corresponds to the upper end frequency in the passband, is formed at a position (on the line L) displaced toward the back busbar 21 from the front busbar 21 by a distance D1. FIG. 3 schematically illustrates a distribution of the above-described pitches P on the input-side IDT electrode 11. Each of the electrode fingers 22 is formed such that the straight line illustrating the distribution of pitches P that bends at the line L.

The output-side IDT electrode 12 is also configured in the same manner as the input-side IDT electrode 11 described above. Specifically, each of the electrode fingers 22 is arranged to enable the elastic waves of the tracks Tr1 to Tr2 to propagate at the back side of the line L, and the elastic waves of the tracks Tr3 (=Tr2) to Tr4 to propagate at the front side of the line L. Thus, on these IDT electrodes 11 and 12, each of the electrode fingers 22 is arranged such that the respective tracks Tr1 to Tr4 line up along the propagation direction of the elastic waves.

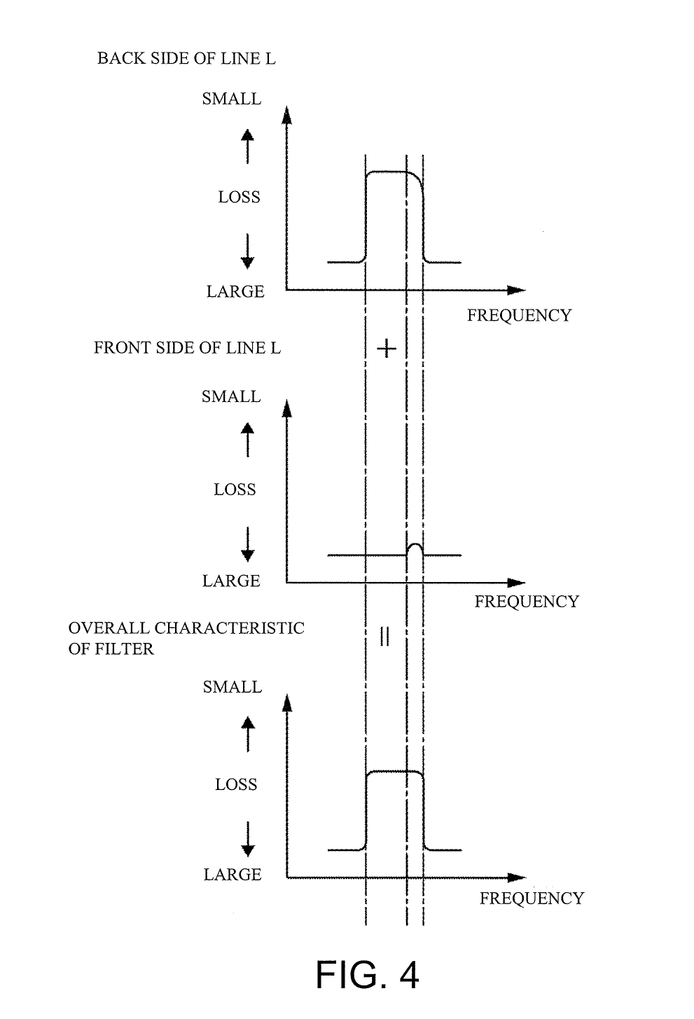

Accordingly, an electrical signal input via an input port 2 to the input-side IDT electrode 11 generates elastic waves corresponding to the respective tracks Tr1 to Tr4 in the input-side IDT electrode 11. Then, the respective elastic waves propagate towards the output-side IDT electrode 12. Here, for example, in the track Tr2 (Tr3) corresponding to the high frequency side band, diffi action and refraction affect the elastic waves to attempt to propagate towards the front side of the line L. In other words, if the filter were configured to have a passband of the frequency band corresponding to the wavelength from the track Tr1 to the track Tr2 only at the back side of the line L, the passband would have what is called “rounded edge” at the high frequency side as illustrated in the top diagram of FIG. 4, and this condition is likely to cause a loss. FIG. 4 schematically illustrates the frequency characteristics.

However, at the front side of the line L, the respective electrode fingers 22 are tapered such that the respective electrode fingers 22 deal with the high frequency side band described above. Even if the elastic waves of the track Tr2 (Tr3) are propagated by diffraction or refraction to the front side of the line L, the electrode fingers 22 disposed in the region enable at least a partial elastic wave energy to be received. Therefore, as illustrated in the middle diagram of the FIG. 4, at the front side of the line L, an attenuation characteristic of a lesser attentuation corresponding to the high frequency side in the passband is obtained so as to compensate for a loss occurring at the back side of the line L. In other words, deterioration of frequency characteristics, such as flatness, in the high frequency side band is anticipated in the conventional configuration. In this disclosure, however, the electrode fingers 22 are preliminarily tapered and arranged at the front side of the line L such that the elastic waves of the track Tr3 and Tr4 corresponding to the high frequency side band are propagated.

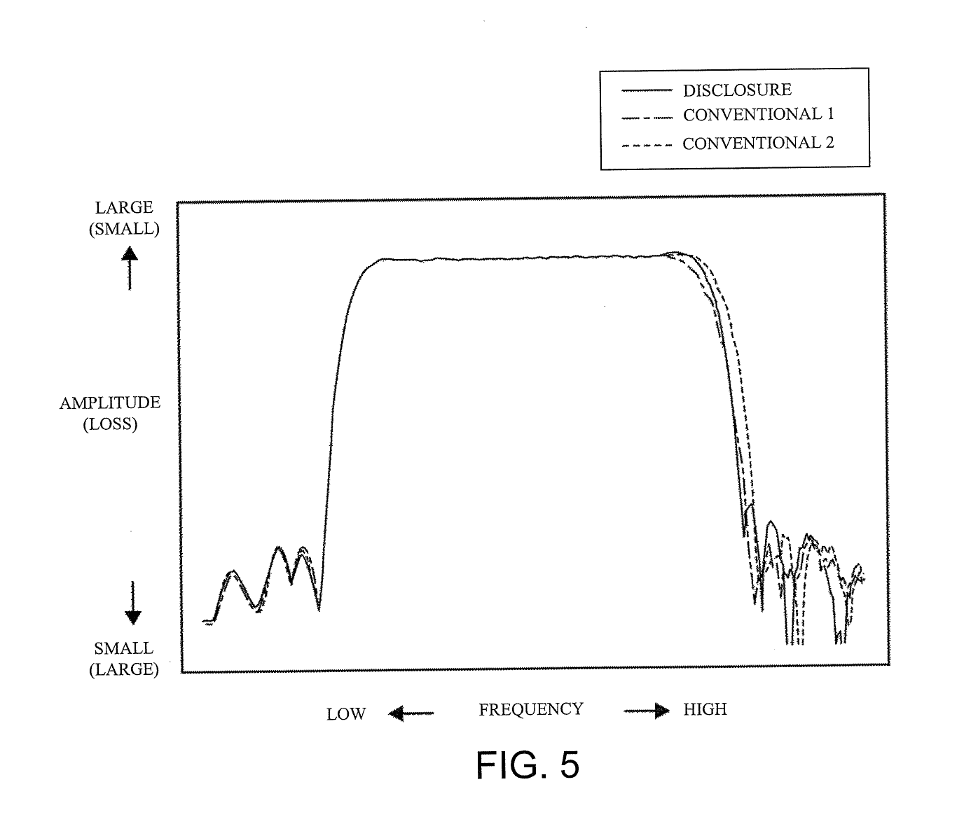

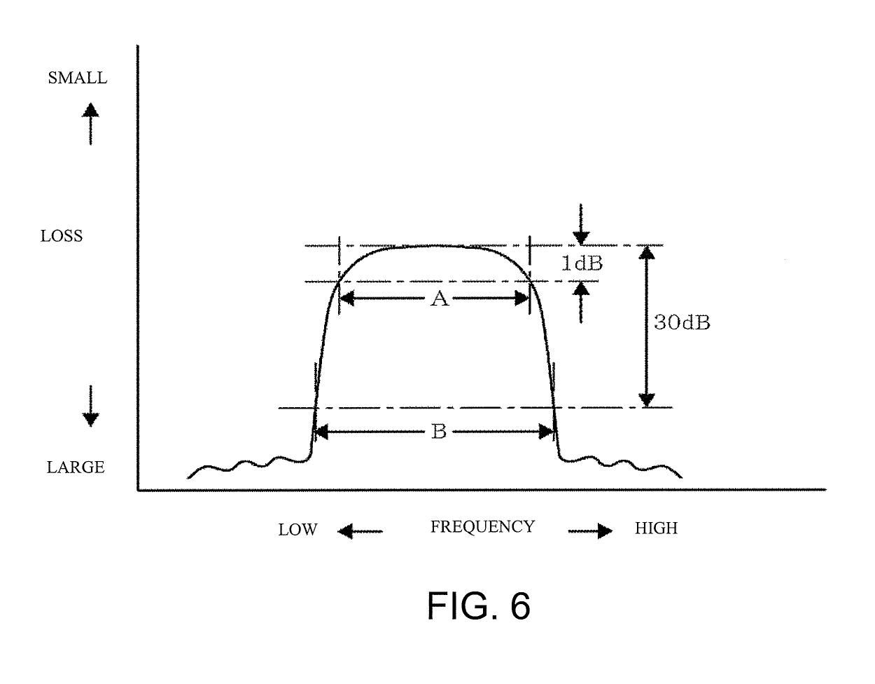

Thus, as illustrated in the bottom diagram of the FIG. 4, the attenuation characteristic at the high frequency side band improves. A preferred flatness is obtained across the passband, the attenuation curve at the high frequency side becomes sharp, and the passband bandwidth accurate to the setting is obtained. FIG. 5 is a simulation of the frequency characteristics of the elastic wave filter described above. As described above, this disclosure provides the preferred flatness and passband bandwidth compared with the conventional filters. Shape factors in FIG. 5 were calculated. The conventional filter 1 and the conventional filter 2 have the shape factors of 1.33 and 1.29 respectively, and this disclosure has the shape factor of 1.26, which is better than those of the conventional filters 1 and 2. As illustrated in FIG. 6, a shape factor indicates sharpness of an attenuation curve in a characteristic diagram illustrating filter characteristics. The shape factor is a ratio of the bandwidth B to the bandwidth A (B/A). The bandwidth A is a band where the attenuation amount is larger than that of the substantially flat attenuation curve area in the passband by 1 dB, and the bandwidth B is a band where the attenuation amount is larger than that of the substantially flat attenuation curve area in the passband by 30 dB.

According to the embodiment described above, for arranging a number of the electrode fingers 22 tapered, the track Tr2, which corresponds to the upper end frequency in the passband, is arranged in a position (line L) displaced toward the back busbar 21 from the front busbar 21 by a distance D1. Because of this, even if some energy is lost by diffraction or refraction of elastic waves corresponding to the high frequency side, the energy is compensated according to the amount of the lost energy at the front side of the line L. In other words, the region at the front side of the line L has, in addition to the track Tr2, which corresponds to the upper end frequency in the passband, a certain band width at the high frequency side in the passband. Thus, the attenuation amount deterioration in the passband and stopbands may be suppressed while keeping the flatness in the pass bandwidth.

As described above, for configuring a filter, the track Tr4, which is positioned close to the front busbar 21, may be set to the pitch same as the PTr1 at the track Tr1, which corresponds to the lower end frequency in the passband. In other words, at the front side of the line L in FIG. 1, the electrode fingers 22 configured in the same manner as those at the back side of the line L may be arranged.

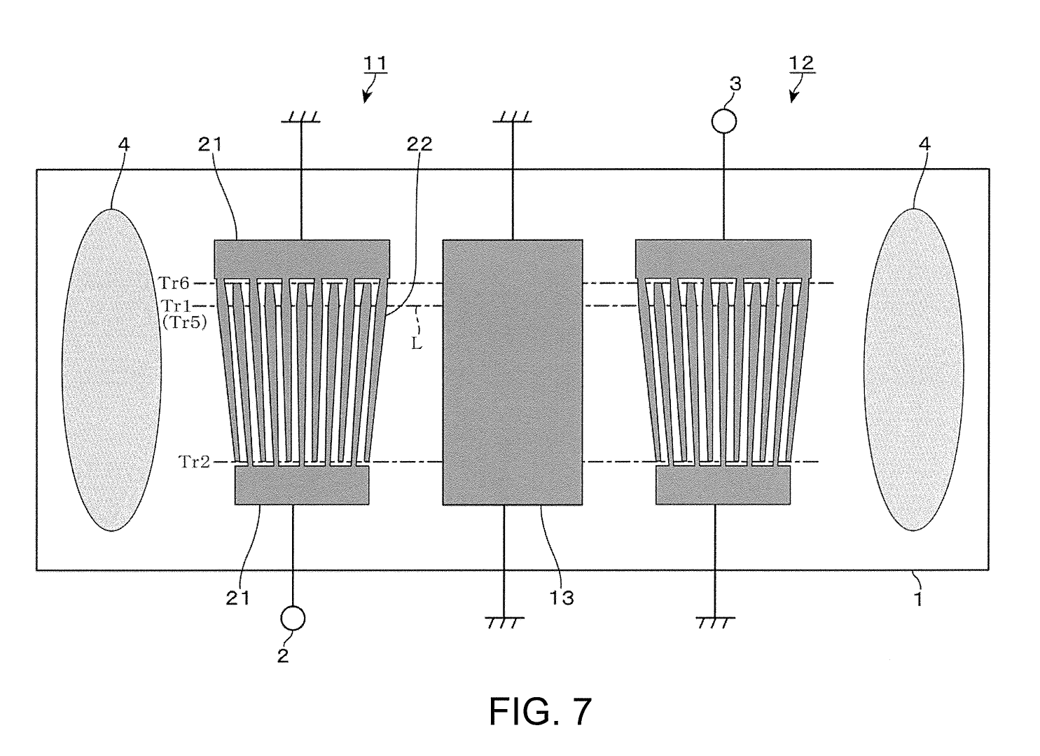

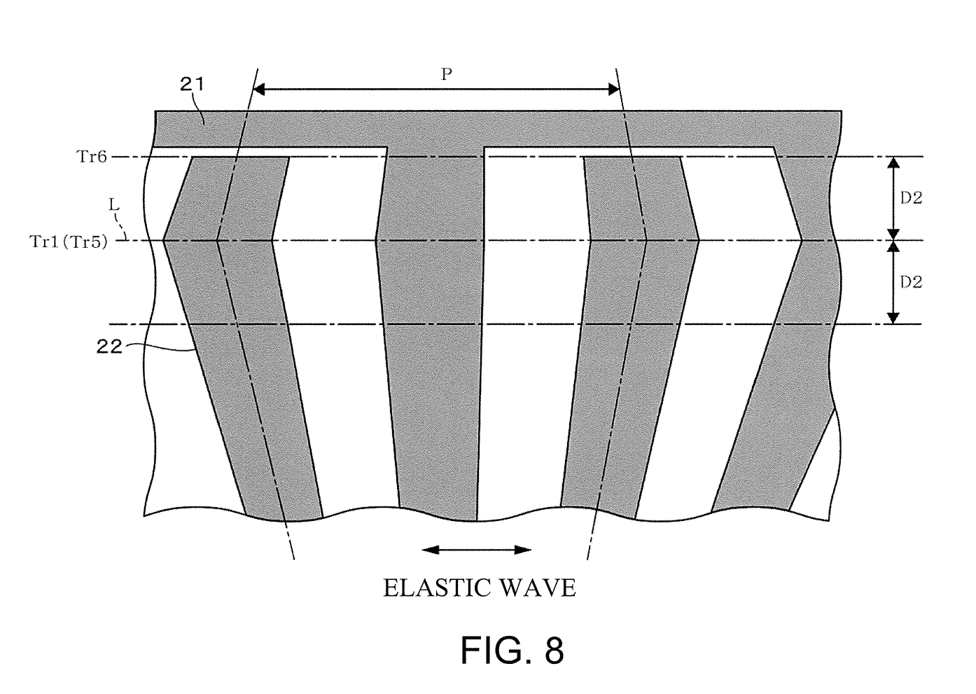

Next, another example of the disclosure will be described. FIG. 7 illustrates an embodiment that suppresses diffraction and refraction in the low frequency side in the passband, instead of diffraction and refraction in the high frequency side in the passband. Specifically, as illustrated in FIG. 8, this example has the line L formed at a distance of dimension D2 away from the back busbar 21 toward the front side. In the region at the front side of the line L, the respective electrode fingers 22 are arranged to enable elastic waves of the tracks Tr1 to Tr2 to propagate. On the other hand, in the region at the back side of the line L, the respective electrode fingers 22 are arranged to enable the elastic waves of the tracks Tr5 to Tr6 to propagate. In the following description, like reference numerals designate corresponding or identical elements of the configuration in FIG. 1, and therefore such elements will not be further elaborated here.

The pitch PTr5 at the track Tr5 is larger than the pitch PTr6 at the track Tr6. In this example, the pitch PTr5 has the same dimension as that of the pitch PTr1. The pitch PTr6 is smaller than the pitch PTr1 and equal to or larger than the pitch PTr2. In this example, PTr1 (PTr5):PTr6=1:0.8 to 1:0.98. Dimension D2 is also 0.5% to 3% of the aperture W.

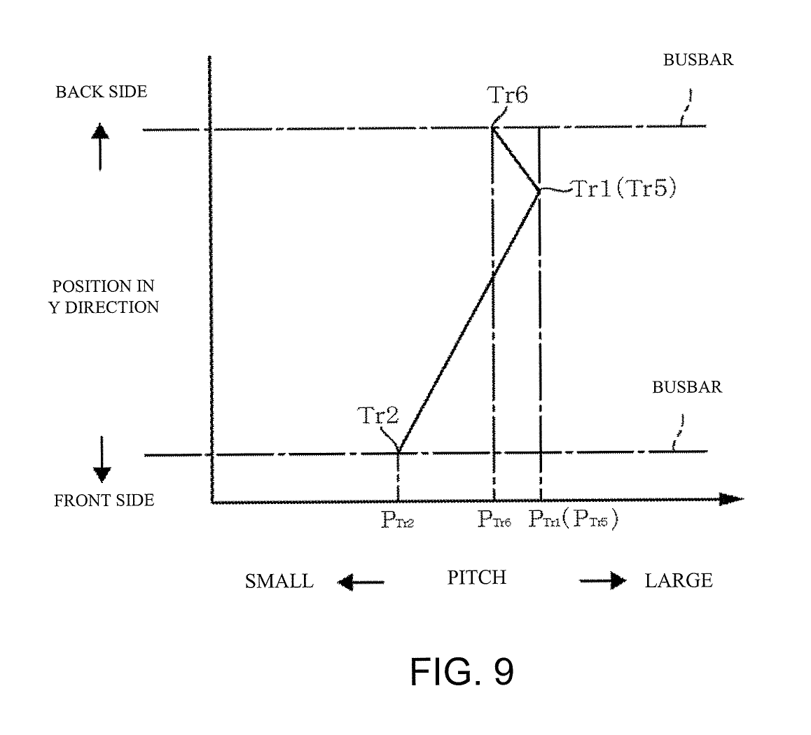

FIG. 9 illustrates a characteristic diagram that schematically summarizes the pitches P of the elastic wave filter. As illustrated in FIG. 9, in this example, the respective electrode fingers 22 are arranged to decrease the pitch P from the pitch PTr1 at the track Tr1 to the pitch PTr2 at the track Tr2 in one region. In the other region of this example, the respective electrode fingers 22 are arranged to decrease the pitch P from the pitch PTr5 at the track Tr5 to the pitch PTr6 at the track Tr6. These two regions are arranged in adjacent to each other (or overlapped each other) in a direction orthogonal to the propagation direction of the elastic waves. Furthermore, between these regions (on line L), the electrode fingers 22 adjacent to each other are connected.

The elastic wave filter thus configured suppresses diffraction and refraction at the low frequency side in the passband, thus ensuring the effect similar to the above mentioned example. Even in this case, the track Tr6 may be set to the pitch same as the pitch PTr2 at the track Tr2, which corresponds to the upper end frequency in the passband.

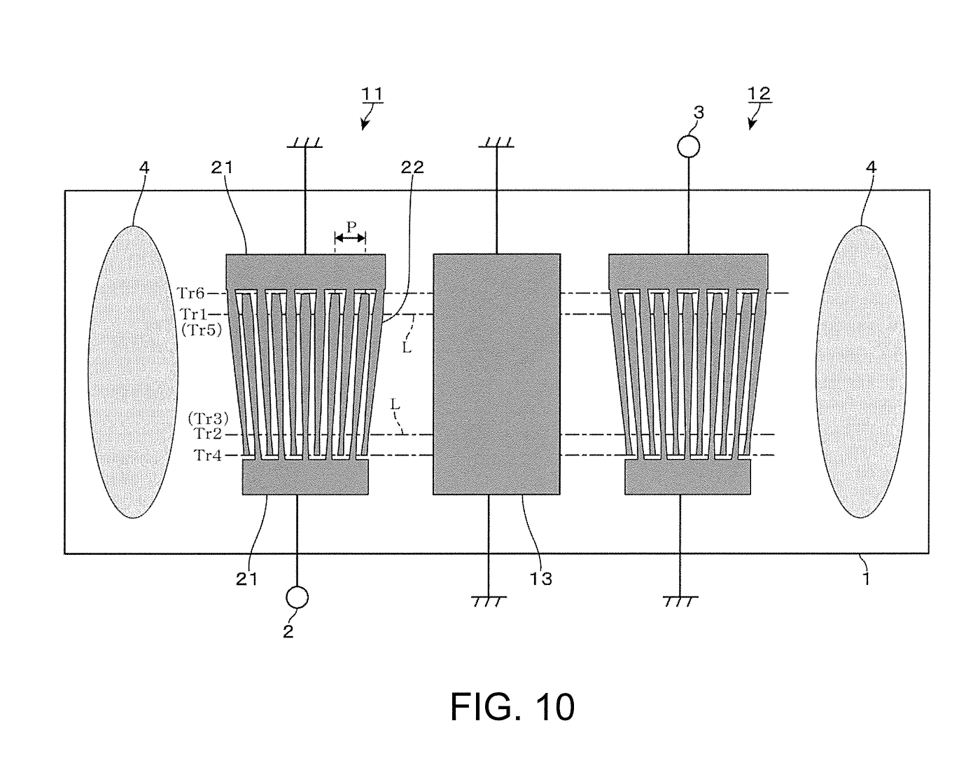

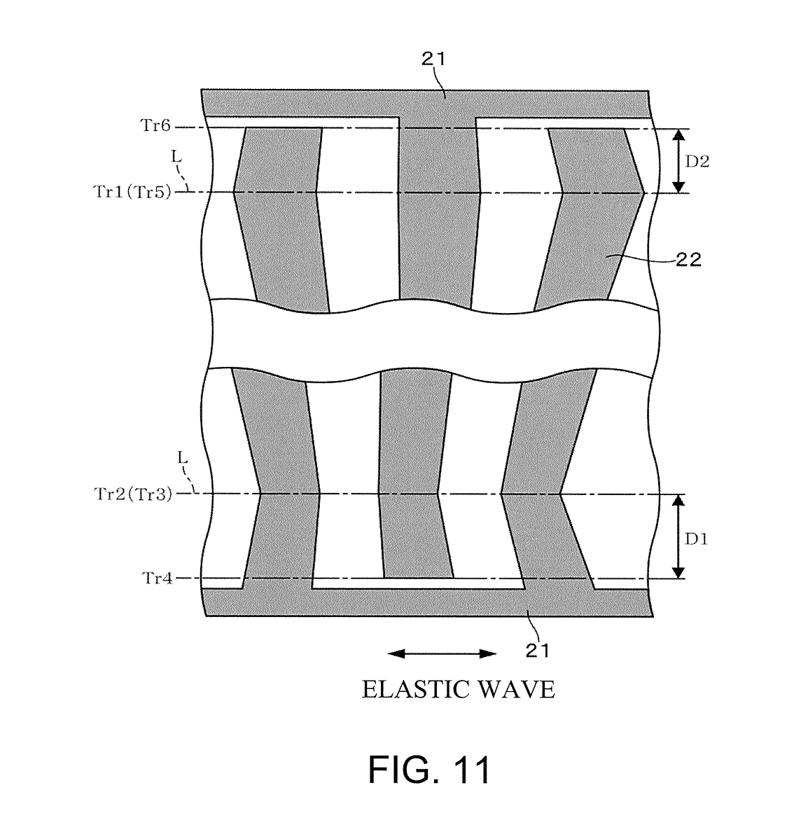

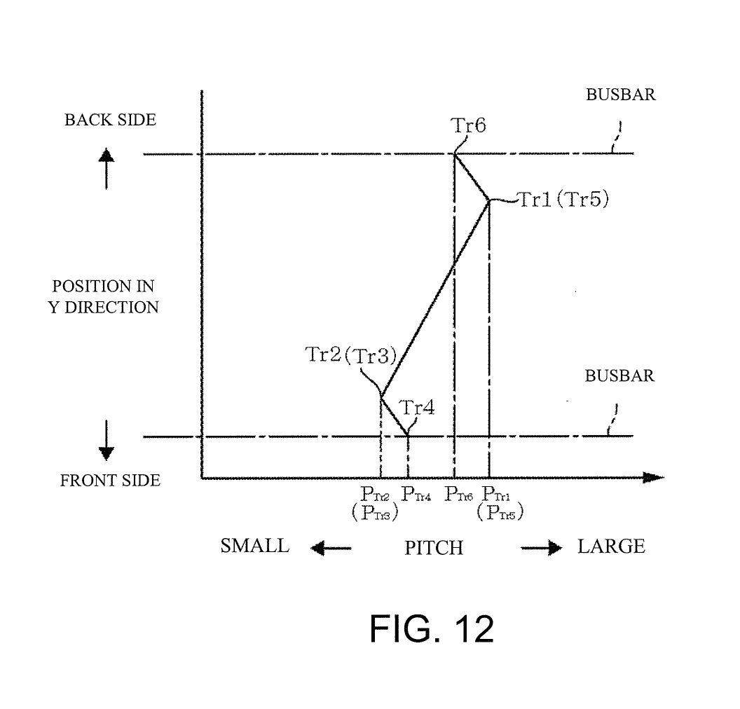

Furthermore, FIG. 10 illustrates a configuration example of a filter that is a combination of the elastic wave filter of FIG. 1 and the elastic wave filter of FIG. 7. In other words, as illustrated in FIG. 11, the lines L are formed at two positions: one is at a distance of dimension D1 away from the front busbar 21 toward the back side; and the other is at a distance of dimension D2 away from the back busbar 21 toward the front side. Thus, as illustrated in FIG. 12 and as described above, the busbars 21 sides of these lines L are configured to enable propagation of the elastic waves at pitches P, which correspond to some portions (the high frequency side and the low frequency side bands) in the passband. In this case, diffraction and refraction are suppressed at both of the high frequency side and low frequency side in the passband, thus ensuring the further satisfactory frequency characteristics.

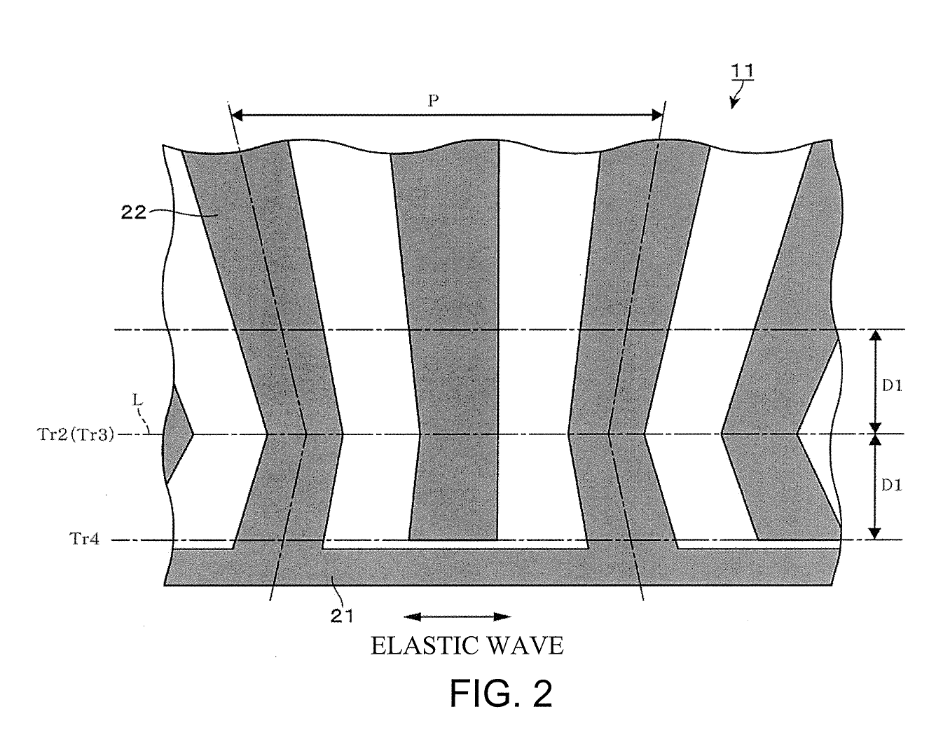

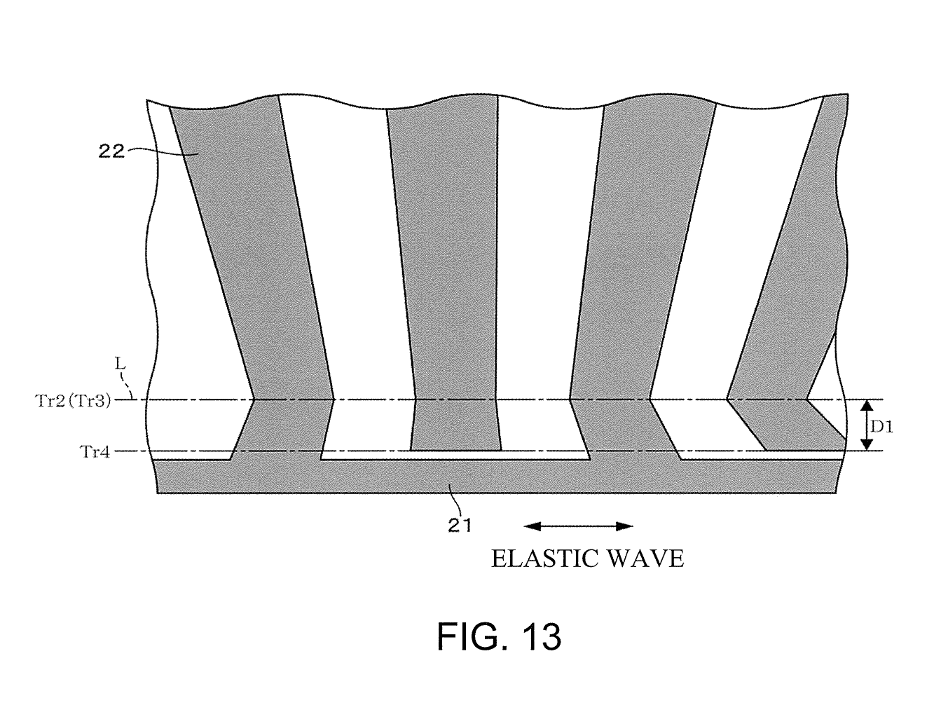

In each of the above examples, the electrode fingers 22 in the region at the busbar 21 side with respect to the line L are adjusted to have the same taper angle as the electrode fingers 22 at the opposite side with respect to the line L. The taper angle, however, may be individually set for those regions. FIG. 13 illustrates an example based on the configurations illustrated by FIG. 1 and FIG. 2. In FIG. 13, by shortening the dimension D1, the taper angle at the front side of the line L is set smaller (reclined) than the taper angle at the back side of the line L. Also by setting the dimension D1 longer than the dimension illustrated in FIG. 2, the taper angle may be set steeper.

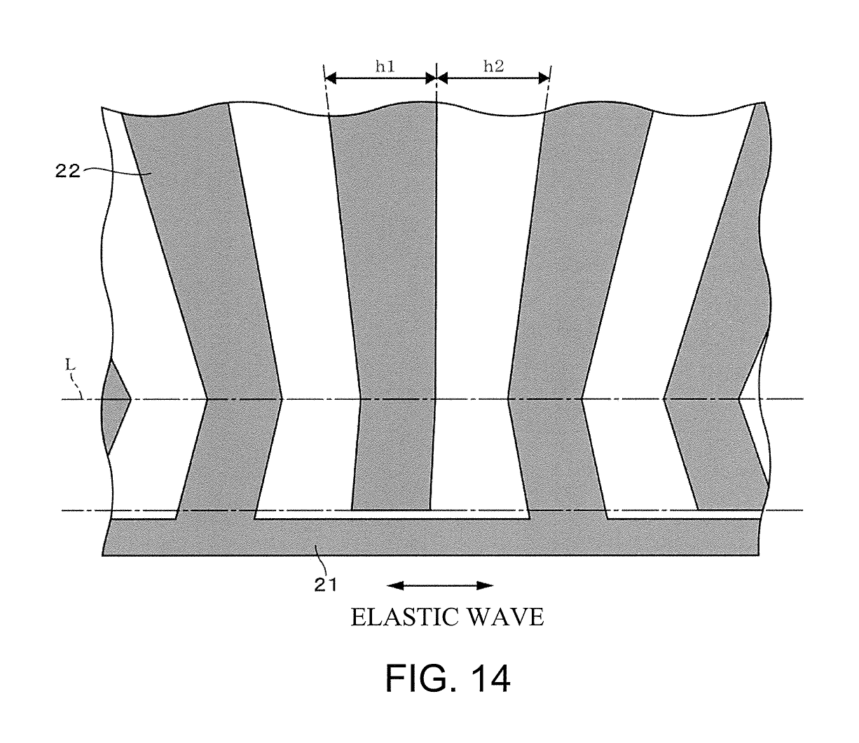

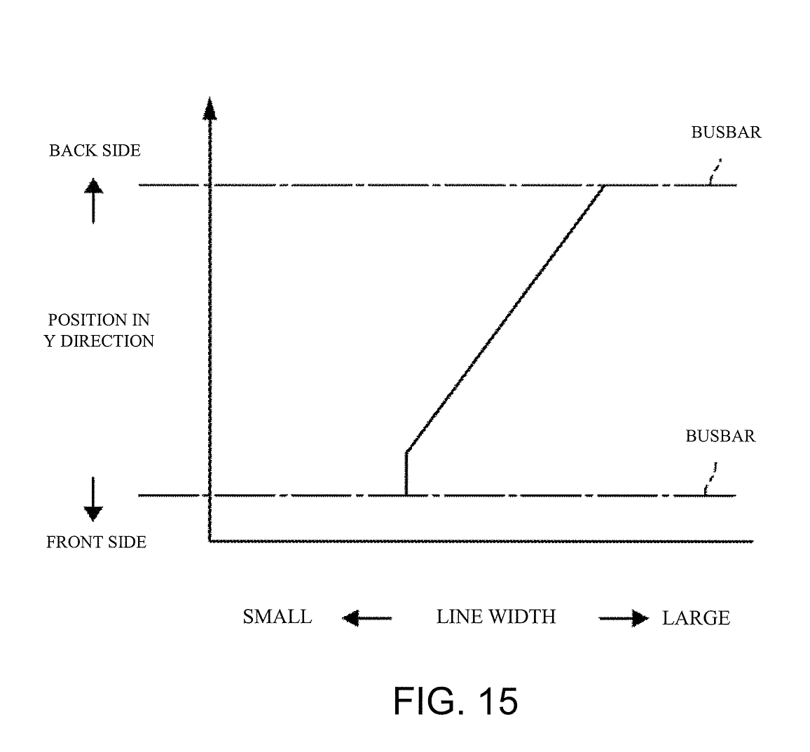

FIG. 14 illustrates an example based on the configuration illustrated by FIG. 1 and FIG. 2. At the front side of the line L in FIG. 14, the pitch P continuously changes between PTr2 and PTr3 in the direction orthogonal to the propagation direction of the elastic waves, and accordingly a width dimension h1 of the electrode fingers 22 and a separation dimension h2 between the adjacent electrode fingers 22 and 22 are adjusted. In other words, as illustrated in FIG. 15, at the front side of the line L, the width dimension hl of the electrode fingers 22 is set to a constant value. Thus, at the front side of the line L, the separation dimension h2 continuously widens from the back side to the front side.

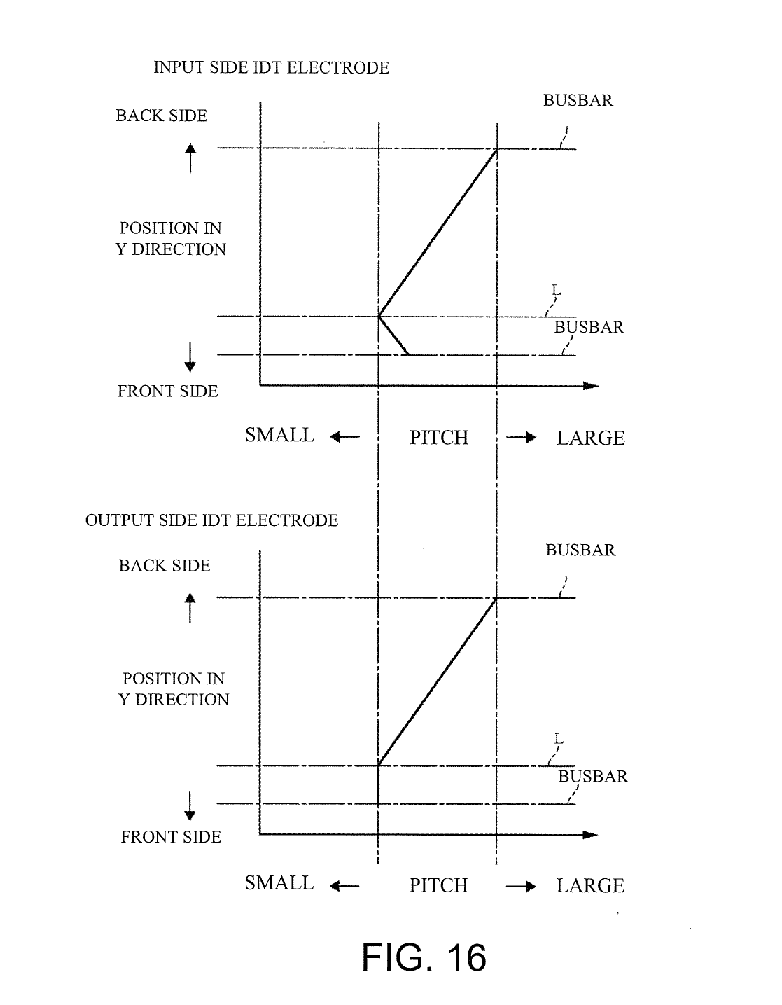

In the examples described above, the input-side IDT electrode 11 and the output-side IDT electrode 12 have the same configuration. However, the IDT electrodes 11 and 12 may have different configurations. FIG. 16 is a distribution diagram of the pitches P for indicating such an example. The input-side IDT electrode 11 employs the configuration illustrated in FIG. As for the output-side IDT electrode 12, at the back side of the line L, the electrode fingers 22 are arranged in the same layout as that of the input-side IDT electrode 11. On the other hand, at the front side of the line L, the pitches P are uniformly set to the pitch PTr2, which corresponds to the upper end frequency in the passband. Thus, the configuration of the output-side IDT electrode 12 is equivalent to the configuration described in the Japanese Patent No. 4707902. Even in this case, an effect similar to the described examples is obtained.

Variation of the pitches P at each of the tracks Tr3 to Tr6 are summarized as follows: PTr1>PTr3≧PTr2, PTr1≧PTr4>PTr2, PTr4>PTr3, PTr1>PTr6≧PTr2, PTr1≧PTr5>PTr2, and PTr5>PTr6.

The elastic wave filter according to the disclosure may have any of the following specific configurations. That is, the elastic wave filter further includes the configuration according to (1). Assuming that a dimension between the pair of busbars is an aperture W, a separation dimension D1 between the track Tr3 and the track Tr4 on the piezoelectric substrate is expressed by 3≧D1/W×100.

The elastic wave filter further includes the configuration according to (2). Assuming that a dimension between the pair of busbars is an aperture W, a separation dimension D2 between the track Tr5 and the track Tr6 on the piezoelectric substrate is expressed by 3>D2/W×100. In the elastic wave filter, the input side IDT electrode and the output side IDT electrode each include at least one of the configuration according to (1) and the configuration according to (2).

The disclosure provides a configuration of a filter where the electrode finger group is formed in a taper shape such that elastic waves with period lengths from a period length at the track Tr1 to a period length at the track Tr2 (Tr1>Tr2) propagate. The track Tr1 (and/or the track Tr2), which is at least one of the track Tr1 and the track Tr2, is separated from the position (the end positions of the electrode fingers) near the busbar in the direction perpendicular to the propagation direction. The electrode finger group is arranged in the period lengths that partially correspond to the passband of the filter at the opposite side of the track Tr2 (the track Tr1) viewed from the other track Tr1 (the track Tr2). Accordingly, even if the elastic waves of the at least one of the track Tr1 (the track Tr2) attempt to propagate to the outside of the region with the electrode finger group due to diffraction or refraction, this outside region also includes the electrode fingers, thus suppressing deterioration of frequency characteristics due to diffraction or refraction of the elastic waves.

The principles, preferred embodiment and mode of operation of the present disclosure have been described in the foregoing specification. However, the disclosure which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present disclosure. Accordingly, it is expressly intended that all such variations, changes and equivalents which fall within the spirit and scope of the present disclosure as defined in the claims, be embraced thereby.

What is claimed is:

1. An elastic wave filter, comprising
an electrode finger group in an input side electrode and an electrode finger group in output side electrode each disposed in a taper shape such that elastic waves with mutually different wavelengths propagate on a piezoelectric substrate across from a track Tr1 at a low frequency side of a passband to a track Tr2 at a high frequency side of the passband, wherein
the input side electrode and the output side electrode each includes a pair of busbars and a plurality of electrode fingers to constitute an input side IDT electrode and an output side IDT electrode respectively, the pair of busbars each extending along a propagation direction of the elastic wave and being arranged mutually separated in a direction perpendicular to the propagation direction, the plurality of electrode fingers alternately extending from each of the pair of busbars toward the opposite busbar in a comb shape between the pair of busbars,
assuming that a period length P is a wavelength of the elastic wave propagating on the piezoelectric substrate and constituted of a width dimension of the finger and a separation dimension between the adjacent electrode fingers, at least one of the input side IDT electrode and the output side IDT electrode includes at least one of following configurations:
(1) The respective electrode fingers are arranged such that the period length P decreases from a period length PTr1 at the track Tr1 to a period length PTr2 at the track Tr2 in one region, the respective electrode fingers are arranged such that the period length P increases from a period length PTr3 at a track Tr3 to a period length PTr4 at a track Tr4 in another region, the one region and the other region are arranged to dispose the track Tr2 and the track Tr3 adjacent, the respective electrode fingers opposed one another between the one region and the other region are connected, and PTr1≧PTr4>PTr3=PTr2; and
(2) The respective electrode fingers are arranged such that the period length P decreases from the period length PTr1 at the track Tr1 to the period length PTr2 at the track Tr2 in one region, the respective electrode fingers are arranged such that the period length P decreases from a period length PTr5 at a track Tr5 to a period length PTr6 at a track Tr6 in another region, the one region and the other region are arranged to dispose the track Tr1 and the track Tr5 adjacent, the respective electrode fingers opposed one another between the one region and the other region are connected, and PTr1=PTr5>PTr6≧PTr2.

2. The elastic wave filter according to claim 1, further comprising
the configuration according to (1), wherein
assuming that a dimension between the pair of busbars is an aperture W, a separation dimension Dl between the track Tr3 and the track Tr4 on the piezoelectric substrate is expressed by 3≧D1/W×100.

3. The elastic wave filter according to claim 1, further comprising
the configuration according to (2), wherein
assuming that a dimension between the pair of busbars is an aperture W, a separation dimension D2 between the track Tr5 and the track Tr6 on the piezoelectric substrate is expressed by 3≧D2/W×100.

4. The elastic wave filter according to claim 1, wherein
the input side IDT electrode and the output side IDT electrode each include at least one of the configuration according to (1) and the configuration according to (2).
